(19) United States
(12) Patent Application Publication
(10) Pub. No.: US 2025/0093208 A1
(43) Pub. Date: Mar. 20, 2025

(54) METHOD AND SYSTEM FOR ONLINE MONITORING OF TEMPERATURE IN CURRENT TERMINAL BLOCKS BASED ON THERMAL IMAGING

(71) Applicant: Yunnan Power Grid Co., Ltd, Kunming City (CN)

(72) Inventors: Yuanhang YANG, Kunming City (CN); Dezhi KONG, Kunming City (CN); Jing CHEN, Kunming City (CN); Hengchu SHI, Kunming City (CN); Hao YOU, Kunming City (CN); Benyu LI, Kunming City (CN); Qiaowei YANG, Kunming City (CN); Lan CHEN, Kunming City (CN); Jiong CHEN, Kunming City (CN); Yigong XIE, Kunming City (CN); Ming ZHAO, Kunming City (CN); Yunkun DENG, Kunming City (CN); Yumin CHEN, Kunming City (CN); Zaihe YANG, Kunming City (CN); Xin WANG, Kunming City (CN); Shan WANG, Kunming City (CN); Zelang WANG, Kunming City (CN); Jianyu ZHOU, Kunming City (CN); Mingqun LIU, Kunming City (CN)

(21) Appl. No.: 18/524,296

(22) Filed: Nov. 30, 2023

(30) Foreign Application Priority Data
Sep. 18, 2023 (CN) 202311199282.8

(51) Int. Cl. G01J 5/90; G01J 5/00

(52) U.S. Cl. CPC G01J 5/90; G01J 5/0096; G01J 2005/0077

(57) ABSTRACT

A method for online monitoring of temperature in current terminal blocks based on thermal imaging are provided, including: obtaining real-time temperature distribution information of current terminals of a terminal box; using an external communication substation to upload the obtained real-time temperature distribution information to the secondary intelligent operation-and-maintenance control platform; determining whether there is an abnormality in temperature of the current terminals, if there is an abnormality, issuing an alarm message about potential danger for an open circuit of a current secondary circuit. The method provided by the present invention has a self-verification function of measurement data and can suppress the influence of ambient temperature. Through aggregation analysis of the temperatures of different current terminals of the terminal box, historical data mining of the temperature of the same current terminal is carried out to identify the hidden dangers of the open circuit of the current secondary circuit.

### TECHNICAL FIELD

The invention relates to the technical field of substation equipment monitoring, in particular to a method and a system for online monitoring of temperature in current terminal blocks based on thermal imaging.

### BACKGROUND

The secondary circuit of the current transformer is responsible for transmitting the current sampling value to apparatuses for protection, measurement and control, metering, involving whether the connection is reliable and directly affects whether the protection device can operate correctly, whether the remote monitoring of the measurement and control device is reliable, and whether the power calculation of the metering instrument is accurate. Accidents such as unplanned equipment outages and burnt terminal boxes due to the open circuit of the secondary circuit of the current transformer occur one after another usually, seriously affecting the safe and stable operation of the power grid. Therefore, it is crucial to promptly discover and eliminate the hidden dangers of the open circuit of the current secondary circuit.

The abnormal temperature rise of the current terminal is one of the most significant characteristics when the open circuit of the secondary circuit of the current transformer occurs. Accordingly, measuring the temperature of the current terminal can serve as an important means to promptly discover and eliminate the hidden danger of the open circuit of the current secondary circuit of the current. Usually, the temperature of the current terminals of the terminal box is mainly measured by the operator periodically holding an infrared thermometer, achieving such the purpose. However, there are problems such as long measurement cycle and large subjective assumptions made by manual judgment. The online measurement of the current terminal temperature is provided as a feasible technical mean for addressing the above problems.

The patent publication number CN110567597A discloses a current terminal block temperature monitoring device, and the patent publication number CN112254823A discloses a temperature measuring device for real-time monitoring of the terminal block temperature. The purpose of these patents is to obtain the current terminal temperature in real time, but the obtained current terminal temperature data is not judged to identify the potential hidden danger in the open circuit of the current secondary circuit.

The patent publication number CN219104211U discloses a relay protection current terminal temperature sensing device, which can identify the hidden danger of the circuit open of the current secondary circuit through the transformation of “colored-to-colorless” and “colorless-to-colored”. However, the higher ambient temperature will also lead to colour changes and thus it is prone to mis-judgment. The patent publication number CN110702262A discloses a current transformer secondary circuit terminal block temperature monitoring system, the patent publication number CN110567597A discloses a current terminal block temperature monitoring device, and the patent publication number CN206945164U discloses a terminal block temperature monitoring-and-alarm circuit. These patents indicate that there is a hidden danger of the open circuit of the current secondary circuit when the temperature of the current terminal reaches the preset temperature threshold, but the accuracy of the judgment based on a single criterion is not high.

The patent publication number CN115436865A discloses a monitoring system and method for a secondary circuit of a current transformer based on infrared thermal imaging. It can determine abnormal current terminals by comprehensively comparing the temperature measurement information of a complete current secondary circuit. However, how to achieve a comprehensive comparison is not determined and described in its content.

Therefore, on the concept of realizing real-time monitoring of current terminal temperature, the following problems still need to be solved in order to timely detect and eliminate hidden dangers of open circuits of current secondary circuit:

(1) With data self-verification function: for temperature measurement components arranged in outdoor terminal boxes, the operating environment is relatively harsh, and there are many intermediate links in data transmission, which can easily lead to data anomalies and frame loss, leading to mis-judgments.

(2) Correcting the influence of environmental heat transfer effect: for the terminal box located in an outdoor high-voltage switching field, in addition to the thermal effect of its own current, the temperature of the outdoor current terminal is also affected by the heat transfer effect of the environment.

(3) The judgment method with strong robustness: in actual operation, the current flowing through the secondary circuit changes with the changing of the system operating mode, and the operating climate conditions of the terminal box also change in a wide range. Engineering applications should be able to overcome the above adverse effects.

### SUMMARY OF INVENTION

In view of the above, the present invention is proposed for those existing problems.

The technical problem addressed by the present invention is that: the existing monitoring method lacks the capability for data self-verification, correction for environmental heat transfer effects, and how to mitigate the adverse effects during actual operation.

In order to solve the above technical problems, the present invention provides the following technical solution: a method for online monitoring of temperature in current terminal blocks based on thermal imaging, including: obtaining real-time temperature distribution information of current terminals of a terminal box; using an external communication substation to upload the obtained real-time temperature distribution information to the secondary intelligent operation-and-maintenance control platform; determining whether there is an abnormality in temperature of the current terminals, if there is an abnormality, issuing an alarm message about potential danger for an open circuit of a current secondary circuit.

As a preferred solution method for a method for online monitoring of temperature in current terminal blocks based on thermal imaging according to the present invention, the real-time temperature distribution information is specifically collected through an online temperature measurement imager so as to collect temperature of the current terminals and obtain all the current terminal temperature distribution information about the terminal box; the uploading the obtained real-time temperature distribution information to the secondary intelligent operation-and-maintenance control platform is specifically performed by processing the information from a collection unit of the external communication substation by a management unit and uploading the same to the secondary intelligent operation-and-maintenance control platform.

As a preferred solution method for a method for online monitoring of temperature in current terminal blocks based on thermal imaging according to the present invention, the determining whether there is an abnormality in the temperature of the current terminals includes defining a reasonableness interval for measurement temperature of the current terminals. When the measured temperature T_{c-i} of the current terminal i is within a reasonableness threshold interval, the measured temperature of the current terminals uploaded to the secondary intelligent operation-and-maintenance control platform is initially confirmed whether it is reasonable data; when the measured temperature T_{c-i} of the current terminal i is outside the reasonableness threshold interval, three consecutive sampling points are determined. If T_{c-i}, T_{c-i}_{⁺¹}, T_{c-i}_{⁺²}, which are three consecutive sampling points, are all outside the reasonableness interval, an alarm for thermal imaging sensor sampling abnormality is issued; if the initially confirming is to be reasonable data, theoretical temperature calibration of the current terminals is performed to confirm that a thermal imaging sensor measurement error is within an allowable range, including calculating the theoretical temperature Tₗ₋ᵢ of the current terminal i based on a secondary current i_{II} uploaded to the secondary intelligent operation-and-maintenance control platform by a power grid relay protection and fault information system, and calculating an error rate k₁ between the measured temperature T_{c-i} and the theoretical temperature Tₗ₋ᵢ of the current terminal i to verify the theoretical temperature; when 0≤k₁≤5%, the data of the measurement temperature of the current terminal uploaded to the secondary intelligent operation-and-maintenance control platform is confirmed to be correct data, and confirming that measurement data is without any errors in intermediate links of transmission and is available for determination of an abnormal temperature of a current terminal; if k₁ does not meet a preset threshold, it is determined that the measurement data has errors due to intermediate transmission links, and a thermal imaging sensor sampling error alarm is issued.

As a preferred solution method for a method for online monitoring of temperature in current terminal blocks based on thermal imaging according to the present invention, the reasonableness interval for the measurement temperature of the current terminals is expressed as:

$$( {T}_{c - i} \geq {T}_{h} ) ⋃ ( {T}_{c - i} \leq {T}_{max} )$$

where, Tₕ represents the current ambient temperature, and Tₘₐₓ represents the historical highest in the measurement temperature of the current terminals;

The theoretical temperature is expressed as:

$${P}_{f} = R * [ \frac{1}{Δ t} {\int }_{t}^{t + Δ t} {i}_{II}^{2} ( t ) dt ]$$

$${P}_{s} = {P}_{s c} + {P}_{s r}$$

$${P}_{s c} = π * {λ}_{f} * ( {T}_{l - i} - {T}_{h} ) * {N}_{u 0}$$

$${P}_{s r} = π * D * {σ}_{B} * ε * ⌊ {( {T}_{l - i} + 237 )}^{4} - {( {T}_{h} + 237 )}^{4} ⌋$$

$${T}_{l - i} = \sum \frac{{P}_{f} - {P}_{s}}{m c} Δ t$$

where, the theoretical temperature Tₗ₋ᵢ of the current terminal i is a function of P_{f} and Pₛ, in which P_{f} and Pₛ correspond to a heating power and a heat dissipation power, respectively, R represents resistance of the current terminal i and its secondary circuit, Δt represents a time interval for uploading the secondary current i_{II} to the power grid relay protection and fault information system, the heat dissipation power Pₛ is the sum of the convection heat dissipation power P_{sc} and the radiation heat dissipation power Pₛᵣ, λ_{f} represents the air thermal conductivity, Tₕ represents the ambient temperature, Nᵤ₀ represents the Nusselt number when the air flow rate is 0, D represents the secondary loop path, σ_{B} represents the Stephan-Boltzmann constant, ε represents the radiation coefficient of the secondary loop wire material, m represents the mass of the secondary loop wire per unit length, and c represents the equivalent specific heat capacity of the secondary loop wire material.

The theoretical temperature calibration is expressed as:

$${k}_{1} = \vert \frac{{T}_{c - i} - {T}_{l - i}}{{T}_{l - i}} \vert * 100 \%$$

where, k₁ represents the error rate.

As a preferred solution method for a method for online monitoring of temperature in current terminal blocks based on thermal imaging according to the present invention, the determining the abnormal temperature of the current terminals includes using an interquartile range method for an aggregative analysis conducted on the measurement temperatures of current terminals of different windings within the terminal box, preliminarily screening out the current terminals with outliers in the measured temperatures, and defining a temperature matrix measured by the current terminals of the different windings.

The matrix is expressed as:

$${T}_{c} = [ \begin{matrix}{T}_{c - A 1} & {T}_{c - A 2} & {T}_{c - A 3} & … & {T}_{c - AN} \\ {T}_{c - B 1} & {T}_{c - B 2} & {T}_{c - B 3} & … & {T}_{c - BN} \\ {T}_{c - C 1} & {T}_{c - C 2} & {T}_{c - C 3} & … & {T}_{c - CN}\end{matrix} ] \\ {M}_{3} = {T}_{c - Ai} , i = int ( \frac{3 ( N + 1 )}{4} + 0.5 ) \\ {M}_{1} + {T}_{c - Ai} , i = int ( \frac{N + 1}{4} + 0.5 ) \\ Z = {M}_{3} + 1.5 * ( {M}_{3} - {M}_{1} ) \\ Y = {M}_{1} - 1.5 * ( {M}_{3} - {M}_{1} )$$

where, T_{c-A1}, T_{c-A2}, T_{c-A3}, T_{c-AN} correspond to the measurement temperatures of the A-phase current terminals of the 1st, 2nd, 3rd, and N windings of the terminal box, respectively, T_{c-B1}, T_{c-B2}, T_{c-B3}, T_{c-BN} correspond to the measurement temperatures of the B-phase current terminals of the 1st, 2nd, 3rd, and N windings of the terminal box, respectively, T_{c-c1}, T_{c-c2}, T_{c-c3}, T_{c-CN} correspond to the measurement temperatures of the C-phase current terminals of the 1st, 2nd, 3rd, and N windings of the terminal box, respectively, in which upper and lower boundaries of a quartile aggregation interval (Y, Z) are defined, M₃ is the 75th percentile value of all elements of T_{c-A} sorted from smallest to largest in columns, M₁ is the 25th percentile value of all elements of T_{c-A} sorted from smallest to largest in columns, and int( ) represents the floor function.

If T_{c-i} falls into the upper and lower boundaries of the quartile aggregation interval (Y, Z), it is determined that the temperature of the current terminal is not outliers and the temperature is normal. If T_{c-i} does not fall into the upper and lower boundaries of the quartile aggregation interval (Y, Z), the current terminal i with the measurement temperature that does not fall into the upper and lower boundaries of the quartile aggregation interval (Y, Z) is screened out, and the standard deviation method is applied to performing aggregation analysis on the measurement temperatures of the three-phase current terminals corresponding to current terminal i.

As a preferred solution method for a method for online monitoring of temperature in current terminal blocks based on thermal imaging according to the present invention, the aggregation analysis is expressed as:

$$\{ \begin{matrix}( {T}_{c - i} \geq {T}_{AVE} - 3 \times sd ) \& ( {T}_{c - i} \leq {T}_{AVE} + 3 \times sd ) \\ {T}_{AVE} = \frac{1}{3} ( {T}_{c - Ai} + {T}_{c - Bi} + {T}_{c - Ci} ) \\ sd = \sqrt{\frac{{( {T}_{c - Ai} + {T}_{AVE} )}^{2} + {( {T}_{c - Bi} - {T}_{AVE} )}^{2} + {( {T}_{c - Ci} - {T}_{AVE} )}^{2}}{2}}\end{matrix}$$

where, T_{AVE} represents the average of the measurement temperature from the three-phase current terminal corresponding to the identified current terminal i, sd represents the standard deviation of the measurement temperature of the three-phase current terminal, T_{c-Ai}, T_{c-Bi}, T_{c-Ci} correspond to the measurement temperatures of phase A, B and C current terminals, respectively, & means AND, that is, it is satisfied at the same time.

When the measurement temperature T_{c-i} of the current terminal i does not meet the aggregation analysis conditions, the phase type of the current terminals with outlier temperature measurements is screened out.

As a preferred solution method for a method for online monitoring of temperature in current terminal blocks based on thermal imaging according to the present invention, after screening out the phase type of the current terminals with outlier temperature measurements, the development trend of the temperature of the current terminals within the time threshold is analyzed to confirm whether there is temperature abnormality in the current terminals; the measurement temperature of the current terminal at the same operating time within the preset time for the current terminal i is extracted for comparison, which is expressed as:

$$\vert {T}_{c - i} - \frac{{T}_{c - i} + {T}_{c - i - 24 h} + {T}_{c - i - 48 h}}{3} \vert \leq 5$$

where, T_{c-i} represents the measurement temperature of current terminal i at the current time, T_{c-i-24h} represents the measurement temperature of current terminal i at the timing 24 hours before the current time, and T_{c-i-48h} represents the measurement temperature of current terminal i at the timing 48 hours before the current time.

When the measurement temperature of the current terminal complies with the threshold, it is judged that the temperature of the current terminal i is normal; when the measurement temperature of the current terminal does not comply with the threshold, the data of the current terminal at different times on the same day is analyzed and a temperature rise function T_{c-i}(t) of the current terminal is defined, which is expressed as:

$${T}_{c - i} ( t ) = \frac{{T}_{c - i} ( t - Δ t ) - {T}_{c - i} ( t )}{Δ t}$$

where, T_{c-i}(t) is the measurement temperature of the current terminal i at time t, T_{c-i}(t−Δt) is the measurement temperature of current terminal i at time t−Δt, and Δt is the time interval for the temperature of the current terminal to be uploaded.

Deriving T_{c-i} (t) to obtain the temperature rise change rate of current terminal i:

$${T}_{c - i}^{′} ( t ) = \frac{{dT}_{c - i} ( t )}{dt}$$

Performing statistical analysis on the actual temperature measurement data, and determining that the temperature of the current terminal i is normal when the temperature rise change rate of the current terminal i complies with the change rate threshold.

The change rate threshold is expressed as:

$${T}_{c - i}^{′} ( t ) = \vert \frac{{dT}_{c - i} ( t )}{dt} \vert \leq 0.3$$

When it does not comply with the change rate threshold, three sampling points are determined consecutively, when none of complies

$$\vert \frac{{dT}_{c - i} ( t )}{dt} \vert , \vert \frac{{dT}_{c - {i}_{+ 1}} ( t )}{dt} \vert , \vert \frac{{dT}_{c - {i}_{+ 2}} ( t )}{dt} \vert$$

with the change rate threshold, it is determined that the current terminal i is a current terminal in an abnormal temperature, and the corresponding secondary circuit is determined to have hidden dangers in an open circuit, thereby issuing an alarm.

Another object of the present invention is to provide a system for online monitoring of temperature in current terminal blocks based on thermal imaging, which can construct a remote safety communication system for distribution network operations, resulting in solving the problem that, the current flowing through the secondary circuit changes with changes in the system operation mode in actual operation, and the operating climate conditions of the terminal box also change in a wide range.

In order to solve the above technical problems, the present invention provides the following technical solution: a system for online monitoring of temperature in current terminal blocks based on thermal imaging, including: a data collection module, a wireless communication module, a management module, a power dispatch module and an operation and maintenance control module; the data collection module collects data through an online temperature measurement thermal imager and transmits the data through the wireless communication module; the wireless communication module is used to transmit the data collected by the data collection module to the management module through wireless communication; the management module is used to receive the data received by the wireless communication module so as to complete collection, processing, storage, and display for temperature distribution of current terminals of a terminal box; the power dispatch module is used to upload the data of the management module to the operation and maintenance control module through a production management area network; the operation and maintenance control module is used to identify temperature distribution information of the current terminals, so as to obtain a measurement temperature of each the current terminal, to determine whether there is an abnormality in the temperature of the current terminals, to identify a current terminal with an abnormal temperature, and to issue potential alarm information for an open circuit of a current secondary circuit.

A computer device includes a memory and a processor. The memory stores a computer program, characterized in that when the processor executes the computer program, it implements the steps of the method for online monitoring of temperature in current terminal blocks based on thermal imaging as afore-described.

A computer-readable storage medium has a computer program stored thereon, characterized in that when the computer program is executed by a processor, the steps of the method for online monitoring of temperature in current terminal blocks based on thermal imaging as afore-described are implemented.

Beneficial effects of the present invention: the method for online monitoring of temperature in current terminal blocks based on thermal imaging provided by the present invention is performed on the temperature of the current terminal for reasonable degree verification theory and reasonable temperature verification, and the second law of thermodynamics is introduced to correct the ambient temperature. It has a self-verification function of measurement data and can suppress the influence of ambient temperature. By aggregation analysis of the temperatures of different current terminals of the terminal box, historical data mining of the temperature of the same current terminal is carried out to identify the hidden dangers of open circuits of the current secondary circuit. The determination results are not affected by changes in operating modes and environments and have strong robustness and higher accuracy.

### BRIEF DESCRIPTION OF DRAWINGS

In order to explain the technical solutions of the embodiments of the present invention more clearly, the drawings needed to be used in the description for the embodiments will be briefly introduced below. Obviously, the drawings in the following description are only for some embodiments of the present invention. For those of ordinary skill in the art, other drawings can be obtained based on these drawings without exerting any creative effort. There are:

FIG. 1 is an overall flow chart of a method for online monitoring of temperature in current terminal blocks based on thermal imaging provided by one embodiment of the present invention.

FIG. 2 is a schematic diagram of an arrangement of an infrared sensor for the method for online monitoring of temperature in current terminal blocks based on thermal imaging provided by a first embodiment of the present invention.

FIG. 3 is an overall structural diagram of a system for online monitoring of temperature in current terminal blocks based on thermal imaging provided by a second embodiment of the present invention

FIG. 4 is a monitoring architecture diagram of a current terminal strip temperature online monitoring system based on thermal imaging provided by the second embodiment of the present invention.

FIG. 5 is a temperature curve diagram of a method for online monitoring of temperature in current terminal blocks based on thermal imaging provided by a fourth embodiment of the present invention.

### DETAILED DESCRIPTION OF THE INVENTION

In order to make the above objects, features and advantages of the present invention more obvious and easy to understand, the specific embodiments of the present invention are described in detail below in conjunction with the accompanying drawings. It is obvious that the described embodiments are part of the embodiments of the present invention, not all of them. Example. Based on the embodiments of the present invention, all other embodiments obtained by ordinary people in the art without creative efforts should fall within the protection scope of the present invention.

Many specific details are set forth in the following description to fully understand the present invention. However, the present invention can also be implemented in other ways different from those described herein. Those skilled in the art can make similar generalizations without violating the significance of the present invention. Therefore, the present invention is not limited by the specific embodiments disclosed below.

Further, “one embodiment” or “an embodiment” as used herein refers to a specific feature, structure, or characteristic that may be included in at least one implementation of the present invention. “In one embodiment” appearing in different places in this specification does not all refer to the same embodiment, nor is it a separate or selective embodiment that is mutually exclusive with other embodiments.

The present invention is described in detail with reference to schematic diagrams. When describing the embodiments of the present invention in detail, for convenience of explanation, the cross-sectional view showing the device structure are enlarged according to the general scale. Moreover, the schematic diagrams are only examples and shall not limit the present invention. scope of protection. In addition, the three-dimensional dimensions of length, width and depth should be included in actual production.

Moreover, in the description of the present invention, it should be noted that the orientation or positional relationship indicated by the terms “upper, lower, inner and outer” are based on the orientation or positional relationship shown in the drawings, and are only for the convenience of describing the present invention. The present invention and simplified description are not intended to indicate or imply that the devices or elements referred to must have a specific orientation, be constructed and operate in a specific orientation, and therefore are not to be construed as limitations of the invention. Furthermore, the terms “first, second or third” are used for descriptive purposes only and are not to be construed as indicating or implying relative importance.

Unless otherwise clearly stated and limited in the present invention, the terms “installation, connection, and connection” should be understood in a broad meaning. For example, it can be a fixed connection, a detachable connection, or an integrated connection; it can also be a mechanical connection, an electrical connection, or a direct connection. A connection can also be indirectly connected through an intermediary, or it can be an internal connection between two components. For those of ordinary skill in the art, the specific meanings of the above terms in the present invention can be understood on a case-by-case basis.

### Embodiment 1

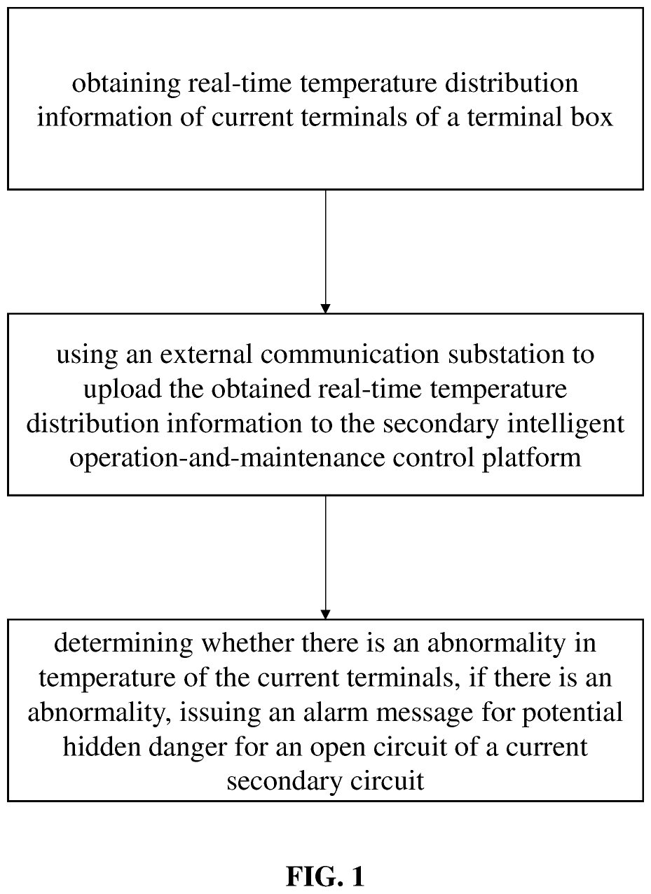

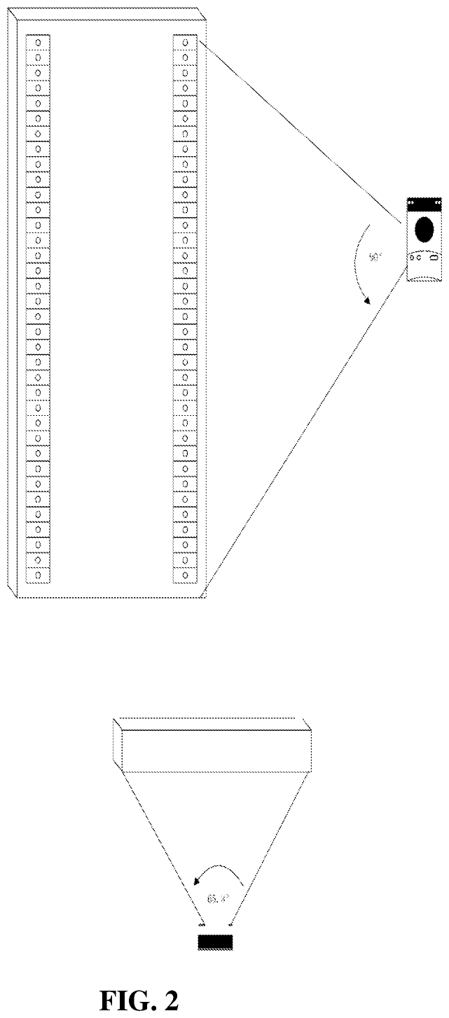

Referring to FIG. 1-FIG. 2, which illustrate an embodiment of the present invention, a method for online monitoring of temperature in current terminal blocks based on thermal imaging is provided, including:

S1: obtaining real-time temperature distribution information of current terminals of a terminal box.

As shown in FIG. 2, the obtaining the real-time temperature distribution information of the current terminals of the terminal box can be achieved by: collecting the temperatures of the current terminals through an online temperature measurement imager. The thermal imaging sensor has a temperature measurement field with a viewing angle in 90°×65.3°, which can quickly, easily and contactlessly obtain the temperature distribution information of all current terminals in the terminal box. After infrared image recognition, the measurement temperature of each current terminal in the terminal box can be further obtained. An online temperature measurement imager corresponds to a primary interval terminal box.

S2: using an external communication substation to upload the obtained real-time temperature distribution information to a secondary intelligent operation-and-maintenance control platform.

The path for uploading the real-time temperature of the current terminals to secondary intelligent operation-and-maintenance control platform is: processing the information from a collection unit of the external communication substation by a management unit and uploading the same to the secondary intelligent operation-and-maintenance control platform.

The external communication substation refers to the device installed at the factory station that is responsible for communicating with the accessed secondary online monitoring device, completing the collection, processing, storage, and display of the temperature distribution of the current terminals of the terminal box, and sending information to the secondary intelligent operation-and-maintenance control platform as required for hardware and software systems.

The collection unit of the external communication substation is responsible for collecting the temperature distribution information of the current terminals of the terminal box, including an online temperature measurement imager. The substation management unit of the external communication substation includes servers, protocol converters, wireless receiving and aggregation units, etc., and it can upload the data sampled by the collection unit to the secondary intelligent operation-and-maintenance control platform through the safety production area III network, namely, the production management area network.

The secondary intelligent operation-and-maintenance control platform refers to the information platform used by the dispatching agency to carry out remote related business for the secondary equipment at the plant and station. It achieves the following functions: identifying the temperature distribution information of the current terminals uploaded by the external communication substation, so as to obtain the measurement temperature of each current terminal; determining whether there is an abnormality in the temperature of the current terminal, identifying any current terminal with abnormal temperature, and issuing alarm information about a potential open circuit in a current secondary circuit.

S3: determining whether there is an in the temperature of the current terminal and issuing alarm information about a potential open circuit in a current secondary circuit if any abnormality is found.

The steps to determine whether there is an in the temperature of the current terminal include: verification of the reasonableness of the measurement temperature of the current terminal. According to the second law of thermodynamics, the temperature of the current terminal should be higher than the ambient temperature under normal circumstances. The reasonableness interval of the measurement temperature of the current terminal is defined as:

$$( {T}_{c - i} \geq {T}_{h} ) ⋃ ( {T}_{c - i} \leq {T}_{max} )$$

where, Tₕ represents the current ambient temperature, and Tₘₐₓ represents the historical highest in the measurement temperature of the current terminals. When the measured temperature T_{c-i} of the current terminal i is within a reasonableness threshold interval, the measured temperature of the current terminals uploaded to the secondary intelligent operation-and-maintenance control platform is initially confirmed whether it is reasonable data, such as the thermal imaging sensor having no data anomalies or frame loss; and the influence of ambient temperature is eliminated to avoid mis-judgment of excessively high current terminal temperatures in hot weather as well.

When the measured temperature T_{c-i} of the current terminal i is outside the reasonableness threshold interval, three consecutive sampling points are determined. If T_{c-i}, T_{c-i}+1, T_{c-i}+2, which are three consecutive sampling points, are all outside the reasonableness interval, an alarm for thermal imaging sensor sampling abnormality is issued, otherwise it goes to the next step.

Theoretical temperature calibration of the current terminals is performed: on the basis of preliminary determination, further carrying out the theoretical temperature calibration of current terminals, to confirm that a thermal imaging sensor measurement error is within an allowable range. It is to calculate the theoretical temperature Tₗ₋ᵢ of the current terminal i based on a secondary current i_{II} uploaded to the secondary intelligent operation-and-maintenance control platform by a power grid relay protection and fault information system:

$${P}_{f} = R * [ \frac{1}{Δ t} {\int }_{t}^{t + Δ t} {i}_{II}^{2} ( t ) dt ] \\ {P}_{s} = {P}_{sc} + {P}_{sr} \\ {P}_{sc} = π * {λ}_{f} * ( {T}_{l - i} - {T}_{h} ) * {N}_{u 0} \\ {P}_{sr} = π * D * {σ}_{B} * ε * ⌊ {( {T}_{l - i} + 237 )}^{4} - {( {T}_{h} + 237 )}^{4} ⌋ \\ {T}_{l - i} = \sum \frac{{P}_{f} - {P}_{s}}{mc} Δ t$$

where, the theoretical temperature Tₗ₋ᵢ of the current terminal i is a function of P_{f} and Pₛ, in which P_{f} and Pₛ correspond to a heating power and a heat dissipation power, respectively, R represents resistance of the current terminal i and its secondary circuit, which can be obtained by measurement, Δt represents a time interval for uploading the secondary current i_{II} to the power grid relay protection and fault information system; the heat dissipation power Pₛ is the sum of the convection heat dissipation power P_{sc} and the radiation heat dissipation power Pₛᵣ, λ_{f} represents the air thermal conductivity, Tₕ represents the ambient temperature, Nᵤ₀ represents the Nusselt number when the air flow rate is 0, D represents the secondary loop path, σ_{B} represents the Stephan-Boltzmann constant, ε represents the radiation coefficient of the secondary loop wire material, m represents the mass of the secondary loop wire per unit length, kg/m, and c represents the equivalent specific heat capacity of the secondary loop wire material.

It is to calculate an error rate k₁ between the measured temperature T_{c-i} and the theoretical temperature Tₗ₋ᵢ of the current terminal i to verify the theoretical temperature, by:

$${k}_{1} = \vert \frac{{T}_{c - i} - {T}_{l - i}}{{T}_{l - i}} \vert * 100 \%$$

According to actual statistical analysis, when 0≤k₁≤5%, the data of the measurement temperature of the current terminal uploaded to the secondary intelligent operation-and-maintenance control platform is confirmed to be correct data, and it is to confirm that measurement data is without any errors in intermediate links of transmission and is available for determination of an abnormal temperature of a current terminal, and then it goes to the next step; otherwise, it is determined that the measurement data has great errors due to intermediate transmission links, and a thermal imaging sensor sampling error alarm is issued.

The real-time uploading of the temperatures of the current terminals and the data processing advantages of the secondary intelligent operation-and-maintenance control platform are fully used. According to the fact that there is no hidden danger in the open circuit of the secondary current circuit, the distribution of measurement temperature data of the different current terminals should show a certain degree of aggregation. The temperatures of different current terminals in the terminal box are merged for comparison, thereby screening out the temperature outlier current terminals and their phase types, by:
firstly, employing the interquartile range method to conduct an aggregative analysis on the measurement temperatures of the current terminals of the various windings within the terminal box, in which preliminary screening is performed to identify current terminals with outlier temperature measurements:
defining a measurement temperatures matrix T_{c} for the current terminals of different windings by:

$${T}_{c} = [ \begin{matrix}{T}_{c - A 1} & {T}_{c - A 2} & {T}_{c - A 3} & … & {T}_{c - AN} \\ {T}_{c - B 1} & {T}_{c - B 2} & {T}_{c - B 3} & … & {T}_{c - BN} \\ {T}_{c - C 1} & {T}_{c - C 2} & {T}_{c - C 3} & … & {T}_{c - CN}\end{matrix} ]$$

where, T_{c-A1}, T_{c-A2}, T_{c-A3}, T_{c-AN} correspond to the measurement temperatures of the A-phase current terminals of the 1st, 2nd, 3rd, and N windings of the terminal box, respectively, T_{c-B1}, T_{c-B2}, T_{c-B3}, T_{c-BN} correspond to the measurement temperatures of the B-phase current terminals of the 1st, 2nd, 3rd, and N windings of the terminal box, respectively, T_{c-c1}, T_{c-c2}, T_{c-c3}, T_{c-CN} correspond to the measurement temperatures of the C-phase current terminals of the 1st, 2nd, 3rd, and N windings of the terminal box, respectively, in which upper and lower boundaries of the quartile aggregation interval (Y, Z) are defined by:

$${M}_{3} = {T}_{c - Ai} , i = int ( \frac{3 ( N + 1 )}{4} + 0.5 )$$

$${M}_{1} = {T}_{c - Ai} , i = int ( \frac{N + 1}{4} + 0.5 ) \\ Z = {M}_{3} + 1.5 * ( {M}_{3} - {M}_{1} ) \\ Y = {M}_{1} - 1.5 * ( {M}_{3} - {M}_{1} )$$

where, M₃ is the 75th percentile value of all elements of T_{c-A} sorted from smallest to largest in columns, M₁ is the 25th percentile value of all elements of T_{c-A} sorted from smallest to largest in columns, and int( ) represents the floor function. If T_{c-i} falls into the upper and lower boundaries of the quartile aggregation interval (Y, Z), it is determined that the temperature of the current terminal is not outliers and the temperature is normal; otherwise, the current terminal i whose measurement temperature does not fall into the upper and lower quartile aggregation interval (Y, Z) is selected and then it goes to the next step.

Since the three-phase current terminals of the same winding are located close to each other, in order to improve the distinction between the adjacent three-phase current terminals and accurately locate the temperature outlier current terminals, the standard deviation method is applied to the aggregation analysis for the measurement temperatures of the three-phase current terminals corresponding to current terminal i:

$$\{ \begin{matrix}( {T}_{c - i} \geq {T}_{AVE} - 3 \times sd ) \& ( {T}_{c - i} \leq {T}_{AVE} + 3 \times sd ) \\ {T}_{AVE} = \frac{1}{3} ( {T}_{c - Ai} + {T}_{c - Bi} + {T}_{c - Ci} ) \\ sd = \sqrt{\frac{{( {T}_{c - Ai} - {T}_{AVE} )}^{2} + {( {T}_{c - Bi} - {T}_{AVE} )}^{2} + {( {T}_{c - Ci} - {T}_{AVE} )}^{2}}{2}}\end{matrix}$$

where, T_{AVE} represents the average of the measurement temperature from the three-phase current terminal corresponding to the identified current terminal i, sd represents the standard deviation of the measurement temperature of the three-phase current terminal, T_{c-Ai}, T_{c-Bi}, T_{c-Ci} correspond to the measurement temperatures of phase A, B and C current terminals, respectively, & means AND, that is, it is satisfied at the same time. When the measurement temperature T_{c-i} of the current terminal i satisfies the above formulas, the phases of the current terminals with the outlier measurement temperatures are screened out and the next step is entered.

By the temperature aggregation analysis to the different current terminals, the current terminals with outlier temperatures and their phase types can be screened out. Analysis to the temperature development trend of the current terminals within a certain time range can be applied to further confirmation whether there is indeed a temperature abnormality in the current terminals. Therefore, the historical data storage and the data processing advantages of the secondary intelligent operation-and-maintenance control platform are can be fully utilized:

For the same current terminal, the change in measurement temperature in the near operating days should be within the allowable range. According to this feature, based on the secondary intelligent operation-and-maintenance control platform, the measurement temperature of the current terminal at the same operating time within the preset time for the current terminal i is extracted for comparison, in which the preset time in the present invention is 3 days:

$$\vert {T}_{c - i} - \frac{{T}_{c - i} + {T}_{c - i - 24 h} + {T}_{c - i - 48 h}}{3} \vert \leq 5$$

where, T_{c-i} represents the measurement temperature of current terminal i at the current time, T_{c-i-24h} represents the measurement temperature of current terminal i at the timing 24 hours before the current time, and T_{c-i-48h} represents the measurement temperature of current terminal i at the timing 48 hours before the current time. According to the actual operation statistical analysis, when the above formula is satisfied, the temperature of the current terminal i is considered normal, otherwise, it is to proceed to the next step.

It is to further narrow the time range and analyze the data of the current terminals at different times on the same day. When the current secondary circuit is reliably connected, the temperature change of the current terminal should be slow. When there is a hidden danger of open circuit in the current secondary circuit, the temperature of the current terminal can produce a large temperature rise in an instant. Based on this point, the current terminal temperature rise function T_{c-i}(t) is defined:

$${T}_{c - i} ( t ) = \frac{{T}_{c - i} ( t - Δ t ) - {T}_{c - i} ( t )}{Δ t}$$

where, T_{c-i}(t) is the measurement temperature of the current terminal i at time t, T_{c-i}(t−Δt) is the measurement temperature of current terminal i at time t−Δt, and Δt is the time interval for the temperature of the current terminal to be uploaded. It is to deriving T_{c-i} (t) to obtain the temperature rise change rate of the current terminal i:

$${T}_{c - i}^{′} ( t ) = \frac{d {T}_{c - i} ( t )}{d t}$$

According to statistical analysis of actual temperature measurement data, when the temperature rise change rate of the current terminal i complies with the following conditions, the temperature of the current terminal i is determined normal; otherwise, three sampling points are determined consecutively; when none of

$$\vert \frac{d {T}_{c - i} ( t )}{dt} \vert , \vert \frac{d {T}_{c - {i}_{+ 1}} ( t )}{dt} \vert , \vert \frac{d {T}_{c - {i}_{+ 2}} ( t )}{dt} \vert$$

complies with the following formula, it is determined that the current terminal i is a current terminal in an abnormal temperature, and the corresponding secondary circuit is determined to have hidden danger in an open circuit, thereby issuing an alarm.

$${T}_{c - i}^{′} ( t ) = \vert \frac{d {T}_{c - i} ( t )}{d t} \vert \leq 0. 3$$

### Embodiment 2

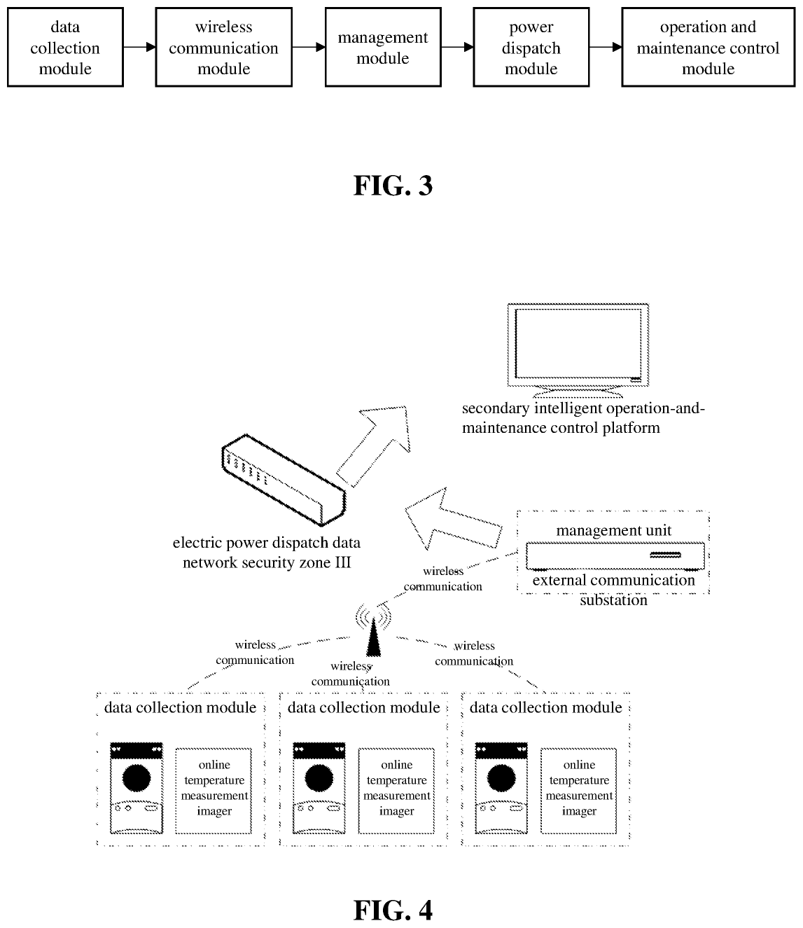

Referring to FIG. 3 to FIG. 4, which illustrate an embodiment of the present invention, a system for online monitoring of temperature in current terminal blocks based on thermal imaging is provided, including: a data collection module, a wireless communication module, a management module, a power dispatch module, and an operation and maintenance control module.

The data collection module collects data through an online temperature measurement thermal imager and transmits the data through the wireless communication module.

The wireless communication module is used to transmit the data collected by the data collection module to the management module through wireless communication.

The management module is used to receive the data received by the wireless communication module so as to complete collection, processing, storage, and display for temperature distribution of current terminals of a terminal box.

The power dispatch module is used to upload the data of the management module to the operation and maintenance control module through a safety production area III network, namely, a production management area network.

As shown in FIG. 4, the operation and maintenance control module is used to identify the temperature distribution information of the current terminals, so as to obtain a measurement temperature of each the current terminal, to determine whether there is an abnormality in the temperature of the current terminals, to identify a current terminal with an abnormal temperature, and to issue potential alarm information for an open circuit of a current secondary circuit.

### Embodiment 3

One embodiment of the present invention is provided and is different than the previous two embodiments with the features:

If the functions are implemented in the form of software functional units and sold or used as independent products, they can be stored in a computer-readable storage medium. Based on this understanding, the technical solution of the present invention essentially or the part that contributes to the existing technology or the part of the technical solution can be embodied in the form of a software product. The computer software product is stored in a storage medium, including several instructions configured to cause a computer device (which may be a personal computer, a server, or a network device, etc.) to execute all or part of the steps of the methods described in various embodiments of the present invention. The aforementioned storage media include: USB flash drive, mobile hard disk, ROM (Read-Only Memory), RAM (Random Access Memory), magnetic disk, or optical disk, which serves as media that can store program code.

The logic and/or steps represented in the flowcharts or otherwise described herein, for example, may be considered a sequenced list of executable instructions for implementing the logical functions, and may be embodied in any computer-readable medium for individually using with or in combination with instruction execution systems, devices or apparatuses (such as computer-based systems, systems including processors or other systems that can fetch instructions from and execute instructions from an instruction execution system, device or apparatus). For the purposes of the present specification, a “computer-readable medium” may be any device that can contain, store, communicate, propagate, or transport a program for use by or in connection with an instruction execution system, apparatus, or device.

More specific examples (non-exhaustive list) of computer readable media include elements as follows: electrical connections with one or more wires (electronic device), portable computer disk cartridges (magnetic device), random access memory (RAM), Read-only memory (ROM), erasable and programmable read-only memory (EPROM or flash memory), fiber optic devices, and portable compact disc read-only memory (CDROM). Furthermore, the computer-readable medium may even be paper or other suitable medium on which the program may be printed. The program may be obtained electronically, for example by optical scanning of paper or other media followed by editing, interpretation or other suitable processing if necessary, and then stored in a computer memory.

It should be understood that various parts of the present invention may be implemented in hardware, software, firmware, or a combination thereof. In the above embodiments, multiple steps or methods may be implemented using software or firmware stored in a memory and executed by a suitable instruction execution system. For example, if it is implemented in hardware, as in another embodiment, it can be implemented by any one or a combination of the following technologies known in the art: discrete logic circuits with logic gates for implementing logical functions on data signals, application specific integrated circuits with suitable combinational logic gates, programmable gate arrays (PGA), field programmable gate arrays (FPGA), etc.

### Embodiment 4

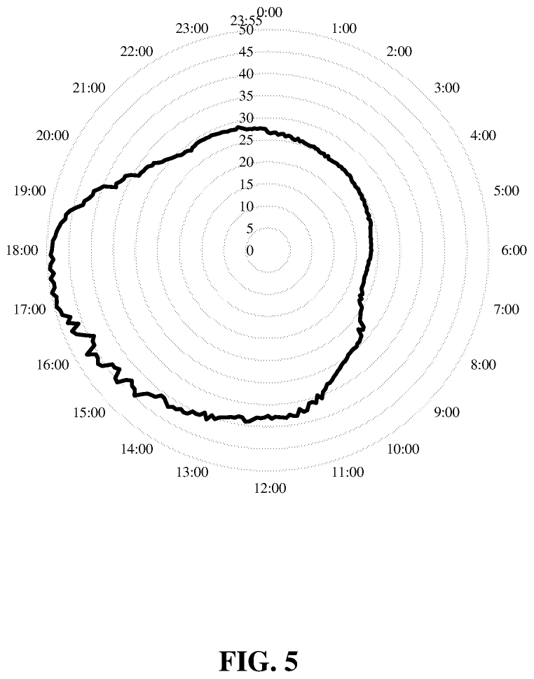

Referring to FIG. 5, which illustrates an embodiment of the present invention, a method for online monitoring of temperature in current terminal blocks based on thermal imaging is provided. In order to verify the beneficial effects of the present invention, scientific demonstration is carried out through economic benefit calculation and simulation experiments.

The measurement temperature of a specific current terminal on a certain 110 kV line at a 220 kV substation on the 18th of month X in 2023 is selected. The method of the present invention is used to perform theoretical temperature verification, reasonableness verification to measured temperature, and ambient temperature correction, so as to complete data self-checking and environmental temperature influence suppression for subsequent determination.

A relay protection current terminal temperature sensing device disclosed in the patent publication number CN219104211U is used to determine the abnormal temperature current terminal through the color change of the temperature sensing material (which the temperature of the thermochromic pigment is 45° C.) and identify the hidden danger in the open circuit of the current secondary circuit.

The method provided by the present invention is used to perform aggregation analysis on the temperatures of the different current terminals, to conduct historical data mining on the temperature of the same current terminal. With the help of the absolute temperature deviation and temperature rise rate of the same current terminal, the potential hidden danger in the open circuit of the current secondary circuit is identified.

The patent publication number CN219104211U is used to identify the hidden danger in the open circuit of the current secondary circuit. When the temperature of the current terminal exceeds 45° C., that is, between 15:40 and 18:45 on the 18th, the color of the temperature-sensing material changes, and the temperature of the current terminal is determined to be abnormal. However, through on-site investigation, it is found that the secondary circuit to which this current terminal belongs is connected reliably, and there is no hidden danger in the open circuit of the secondary circuit. The temperature higher than 45° C. between 15:40 and 18:45 on the 18th is the result of a combination of factors such as ambient temperature and operating mode. The method proposed in the patent of CN219104211U cannot eliminate the influence of ambient temperature, and uses the single criterion of color change, which misjudges the temperature abnormality of the current terminal. The experimental results are shown in FIG. 5.

By using the method provided by the present invention, the data at 17:00 on the 18th is used as an example to make the determination (the measured temperature corresponding to the current terminal i is 49.5° C.). Via the secondary intelligent operation-and-maintenance control platform, the measured temperatures of the current terminals of the four current windings within the required terminal box are extracted for assessment, and the results are shown in Table 1.

As seen from Table 1, the method provided by the present invention is used to determine that there is no abnormality in the temperature of the current terminal, which is consistent with the on-site investigation. The determination results are not affected by changes in operating mode and environment, and are made with strong robustness and high accuracy.

TABLE 1
Identification table of current terminals of a certain 110 kV line in a certain 220 kV
substation at a date 18 of month X in 2023

| | | Determination |
|---|---|---|
| | Data and determination process | result |
| the measured temperatures of the current terminals of the four current | ${T}_{c} = [ \begin{matrix}{T}_{c - A 1} = 48.9 & {T}_{c - A 2} = 49.5 & {T}_{c - A 3} = 49.1 & {T}_{c - A 4} = 48.8 \\ {T}_{c - B 1} = 48.8 & {T}_{c - B 2} = 49.2 & {T}_{c - B 3} = 49. & {T}_{c - B 4} = 48.9 \\ {T}_{c - C 1} = 48.8 & {T}_{c - C 2} = 49.3 & {T}_{c - C 3} = 49.2 & {T}_{c - C 4} = 49.\end{matrix} ]$ M₃ = 49.2 | No current terminal with outlier temperature, temperature of current terminal is |
| windings within | M₁ = 48.8 | normal |
| the terminal box | Y = 48.8 − 1.5 * (49.2 − 48.8) = 48.2 | |
| | Z = 49.2 + 1.5 * (49.2 − 48.8) = 49.8 | |

It should be noted that the above embodiments are provided for the purpose of illustrating the technical solution of the present invention and should not be considered as limiting. Although reference has been made to preferred embodiments for a detailed description of the present invention, those skilled in the art should understand that modifications or equivalent replacements can be made to the technical solution of the present invention without departing from the spirit and scope of the invention, all of which are encompassed within the scope of the claims of the present invention.

What is claimed is:

1. A method for online monitoring of temperature in current terminal blocks based on thermal imaging, comprising:
obtaining real-time temperature distribution information of current terminals of a terminal box;
using an external communication substation to upload the obtained real-time temperature distribution information to the secondary intelligent operation-and-maintenance control platform;
determining whether there is an abnormality in temperature of the current terminals, if there is an abnormality, issuing an alarm message for potential hidden danger for an open circuit of a current secondary circuit,
wherein the determining whether there is an abnormality in the temperature of the current terminals comprises defining a reasonableness interval for measurement temperatures of the current terminals, wherein when a measured temperature T_{c-i} of a current terminal i is within a reasonableness threshold interval, the measured temperature of the current terminal uploaded to the secondary intelligent operation-and-maintenance control platform is initially confirmed whether it is reasonable data;
wherein when the measured temperature T_{c-i} of the current terminal i is outside the reasonableness threshold interval, three consecutive sampling points are determined, if T_{c-i}, T_{c-i}_{⁺¹}, T_{c-i}_{⁺²}, which are three consecutive sampling points, are all outside the reasonableness interval, an alarm for thermal imaging sensor sampling abnormality is issued;
wherein if the initially confirming is to be reasonable data, theoretical temperature calibration of the current terminals is performed to confirm that a thermal imaging sensor measurement error is within an allowable range, comprising calculating the theoretical temperature Tₗ₋ᵢ of the current terminal i based on a secondary current i_{II} uploaded to the secondary intelligent operation-and-maintenance control platform by a power grid relay protection and fault information system, and calculating an error rate k₁ between the measured temperature T_{c-i} and the theoretical temperature Tₗ₋ᵢ of the current terminal i to verify the theoretical temperature;
wherein when 0≤k₁≤5%, the data of the measurement temperature of the current terminal uploaded to the secondary intelligent operation-and-maintenance control platform is confirmed to be correct data, and it is to confirm that measurement data is without any errors in intermediate links of transmission and is available for determination of an abnormal temperature of a current terminal;
wherein if k₁>5%, it is determined that the measurement data has errors due to intermediate transmission links, and a thermal imaging sensor sampling error alarm is issued;
wherein the real-time temperature distribution information is collected through an online temperature measurement imager processing collection to the temperature distribution information of all the current terminals of the terminal box;
wherein the temperature distribution information uploaded to the secondary intelligent operation-and-maintenance control platform, including information from a collection unit of the external communication substation, is uploaded to the secondary intelligent operation-and-maintenance control platform after processing by a management unit;
wherein the reasonableness interval for the measurement temperature of the current terminal is expressed as:
$$( {T}_{c - i} \geq {T}_{h} ) ⋃ ( {T}_{c - i} \leq {T}_{max} )$$
where, Tₕ represents a current ambient temperature, and Tₘₐₓ represents the historical highest in the measurement temperature of the current terminal;
wherein the theoretical temperature is expressed as:
$${P}_{f} = R * [ \frac{1}{Δ t} {\int }_{t}^{t + Δ t} {i}_{II}^{2} ( t ) d t ] \\ {P}_{s} = {P}_{s c} + {P}_{s r} \\ {P}_{s c} = π * {λ}_{f} * ( {T}_{l - i} - {T}_{h} ) * {N}_{u 0} \\ {P}_{s r} = π * D * {σ}_{B} * ε * [ {( {T}_{l - i} + 237 )}^{4} - {( {T}_{h} + 237 )}^{4} ] \\ {T}_{l - i} = \sum \frac{{P}_{f} - {P}_{s}}{m c} * Δ t$$
where, the theoretical temperature Tₗ₋ᵢ of the current terminal i is a function of P_{f} and Pₛ, in which P_{f} and Pₛ correspond to Joule heating power and heat dissipation power, respectively, R represents resistance of the current terminal i and its secondary circuit, Δt represents a time interval for uploading the secondary current i_{II} to the power grid relay protection and fault information system, the heat dissipation power Pₛ is the sum of convection heat dissipation power P_{sc} and radiation heat dissipation power Pₛᵣ, λ_{f} represents an air thermal conductivity, Tₕ represents a ambient temperature, Nᵤ₀ represents a Nusselt number when air flow rate is 0, D represents a secondary loop path, σ_{B} represents a Stephan-Boltzmann constant, ε represents a radiation coefficient of a secondary loop wire material, m represents a mass of a secondary loop wire per unit length, and c represents an equivalent specific heat capacity of a secondary loop wire material,
wherein the theoretical temperature calibration is expressed as:
$${k}_{1} = \vert \frac{{T}_{c - i} - {T}_{l - i}}{{T}_{l - i}} \vert * 100 \%$$
where, k₁ represents an error rate;
wherein the determining the abnormal temperature of the current terminals comprises using an interquartile range method for an aggregative analysis conducted on the measurement temperatures of current terminals of different windings within the terminal box, preliminarily screening out the current terminals with outliers in the measurement temperatures, and defining a temperature matrix measured by the current terminals of the different windings;
wherein the matrix is expressed as:
$${T}_{c} = [ \begin{matrix}{T}_{c - A 1} & {T}_{c - A 2} & {T}_{c - A 3} & … & {T}_{c - AN} \\ {T}_{c - B 1} & {T}_{c - B2} & {T}_{c - B 3} & … & {T}_{c - BN} \\ {T}_{c - C 1} & {T}_{c - C 2} & {T}_{c - C 3} & … & {T}_{c - CN}\end{matrix} ] \\ {M}_{3} = {T}_{c - A i} , i = int ( \frac{3 * ( N + 1 )}{4} + 0.5 ) \\ {M}_{1} = {T}_{c - A i} , i = int ( \frac{N + 1}{4} + 0.5 ) \\ Z = {M}_{3} + 1.5 * ( {M}_{3} - {M}_{1} ) \\ Y = {M}_{1} - 1.5 * ( {M}_{3} - {M}_{1} )$$
where, T_{c-A1}, T_{c-A2}, T_{c-A3}, T_{c-AN} correspond to the measurement temperatures of A-phase current terminals of the 1st, 2nd, 3rd, and N windings of the terminal box, respectively, T_{c-B1}, T_{c-B2}, T_{c-B3}, T_{c-BN} correspond to the measurement temperatures of B-phase current terminals of the 1st, 2nd, 3rd, and N windings of the terminal box, respectively, T_{c-c1}, T_{c-C2}, T_{c-c3}, T_{c-CN} correspond to the measurement temperatures of C-phase current terminals of the 1st, 2nd, 3rd, and N windings of the terminal box, respectively, in which upper and lower boundaries of a quartile aggregation interval (Y, Z) are defined, M₃ is the 75th percentile value of all elements of T_{c-A} sorted from smallest to largest in columns, M₁ is the 25th percentile value of all elements of T_{c-A} sorted from smallest to largest in columns, and int( ) represents a floor function,
wherein If T_{c-i} falls into the upper and lower boundaries of the quartile aggregation interval (Y, Z), it is determined that the temperature of the current terminal is not outliers and the temperature is normal, wherein if T_{c-i} does not fall into the upper and lower boundaries of the quartile aggregation interval (Y, Z), the current terminal i with the measurement temperature that does not fall into the upper and lower boundaries of the quartile aggregation interval (Y, Z) is screened out, and a standard deviation method is applied to performing aggregation analysis on the measurement temperature of the three-phase current terminal corresponding to current terminal i;
wherein the aggregation analysis is expressed as:
$$\{ \begin{matrix}( {T}_{c - i} \geq {T}_{AVE} - 3 * sd ) \& ( {T}_{c - i} \leq {T}_{AVE} + 3 * s d ) \\ {T}_{AVE} = \frac{1}{3} ( {T}_{c - A i} + {T}_{c - B i} + {T}_{c - C i} ) \\ s d = \sqrt{\frac{{( {T}_{c - A i} - {T}_{AVE} )}^{2} + {( {T}_{c - B i} - {T}_{AVE} )}^{2} + {( {T}_{c - C i} - {T}_{AVE} )}^{2}}{2}}\end{matrix}$$
where, T_{AVE} represents an average of the measurement temperature from the three-phase current terminal corresponding to the identified current terminal i, sd represents standard deviation of the measurement temperature of the three-phase current terminal, T_{c-Ai}, T_{c-Bi}, T_{c-Ci} correspond to measurement temperatures of phase A, B and C current terminals, respectively, & means AND, that is, it is satisfied at the same time;
wherein when the measurement temperature T_{c-i} of the current terminal i does not meet aggregation analysis conditions, a phase type of current terminals with outlier temperature measurements is screened out;
wherein, after screening out the phase type of the current terminals with outlier temperature measurements, development trend of the temperature of the current terminals within the time threshold is analyzed to confirm whether there is temperature abnormality in the current terminals, wherein the measurement temperature of the current terminal at the same operating time within a preset time for the current terminal i is extracted for comparison, which is expressed as:
$$\vert {T}_{c - i} - \frac{{T}_{c - i} + {T}_{c - i - 24 h} + {T}_{c - i - 48 h}}{3} \vert \leq 5$$
where, T_{c-i} represents the measurement temperature of current terminal i at current time, T_{c-i-24h} represents the measurement temperature of current terminal i at the timing 24 hours before the current time, and T_{c-i-48h} represents the measurement temperature of current terminal i at the timing 48 hours before the current time;
wherein when the measurement temperature of the current terminal complies with the threshold, it is judged that the temperature of the current terminal i is normal, wherein when the measurement temperature of the current terminal does not comply with the threshold, data of the current terminal at different times on the same day is analyzed and a temperature rise function T_{c-i}(t) of the current terminal is defined, which is expressed as:
$${T}_{c - i} ( t ) = \frac{{T}_{c - i} ( t - Δ t ) - {T}_{c - i} ( t )}{Δ t}$$
where, T_{c-i}(t) is the measurement temperature of the current terminal i at time t, T_{c-i}(t−Δt) is the measurement temperature of the current terminal i at time t−Δt, and Δt is a time interval for the temperature of the current terminal to be uploaded;
wherein T_{c-i} (t) is derived to obtain a temperature rise change rate of the current terminal I, expressed as:
$${T}_{c - i}^{′} ( t ) = \frac{d {T}_{c - i} ( t )}{d t}$$
wherein statistical analysis is performed on actual temperature measurement data, and it is determined that the temperature of the current terminal i is normal when the temperature rise change rate of the current terminal i complies with the change rate threshold;
wherein the change rate threshold is expressed as:
$${T}_{c - i}^{′} ( t ) = \vert \frac{d {T}_{c - i} ( t )}{d t} \vert \leq 0. 3$$
wherein when it does not comply with the change rate threshold, three sampling points are determined consecutively, when none of
$$\vert \frac{d {T}_{c - i} ( t )}{dt} \vert , \vert \frac{d {T}_{c - {i}_{+ 1}} ( t )}{dt} \vert , \vert \frac{d {T}_{c - {i}_{+ 2}} ( t )}{dt} \vert$$
complies with the change rate threshold, it is determined that the current terminal i is a current terminal in an abnormal temperature, and a corresponding secondary circuit is determined to have hidden dangers in an open circuit, thereby issuing an alarm.

2. A system for adopting the method for online monitoring of temperature in current terminal blocks based on thermal imaging according to claim 1, comprising: a data collection module, a wireless communication module, a management module, a power dispatch module, and an operation and maintenance control module;
wherein the data collection module collects data through an online temperature measurement thermal imager and transmits the data through the wireless communication module;
wherein the wireless communication module is used to transmit the data collected by the data collection module to the management module through wireless communication;
wherein the management module is used to receive the data received by the wireless communication module so as to complete collection, processing, storage, and display for temperature distribution of current terminals of a terminal box;
wherein the power dispatch module is used to upload the data of the management module to the operation and maintenance control module through a production management area network;
wherein the operation and maintenance control module is used to identify temperature distribution information of the current terminals, so as to obtain a measurement temperature of each current terminal, to determine whether there is an abnormality in the temperature of the current terminals, to identify a current terminal with an abnormal temperature, and to issue potential alarm information for an open circuit of a current secondary circuit.

3. A computer device comprising a memory and a processor, wherein the memory stores a computer program, characterized in that when the processor executes the computer program, it implements steps of the method for online monitoring of temperature in current terminal blocks based on thermal imaging according to claim 1.

4. A computer readable storage media has a computer program stored thereon, characterized in that when the computer program is executed by a processor, steps of the method for online monitoring of temperature in current terminal blocks based on thermal imaging according to claim 1 are implemented.
